(19) United States
(12) Patent Application Publication
(10) Pub. No.: US 2025/0349512 A1
(43) Pub. Date: Nov. 13, 2025

(54) PLASMA PROCESSING DEVICE, POWER SUPPLY SYSTEM, AND CONTROL METHOD

(71) Applicant: Tokyo Electron Limited, Tokyo (JP)

(72) Inventors: Yuto KOSAKA, Miyagi (JP); Sergey BOLOTOV, Miyagi (JP)

(73) Assignee: Tokyo Electron Limited, Tokyo (JP)

(21) Appl. No.: 19/277,432

(22) Filed: Jul. 23, 2025

Related U.S. Application Data
(63) Continuation of application No. PCT/JP2024/001919, filed on Jan. 23, 2024.

(30) Foreign Application Priority Data
Feb. 3, 2023 (JP) 2023-015585

(51) Int. Cl. H01J 37/32

(52) U.S. Cl. CPC H01J 37/32128; H01J 37/32146; H01J 37/32165; H01J 37/32174

(57) ABSTRACT

In a plasma processing device, power supply circuitry uses, when the degree of reflection of source radio-frequency power in an n-th phase period in an i-th waveform cycle of an electrical bias is greater than a predetermined value, a frequency obtained by adding a shift value Δf[n] to a source frequency f[i,n] as a source frequency for the n-th phase period in the subsequent waveform cycle and changes the sign of the shift value Δf[n] when the degree of reflection in the n-th phase period is on an upward trend in waveform cycles up to the i-th waveform cycle. A radio-frequency power supply changes the sign of the shift value Δf[n] when the source frequencies in the phase periods preceding and subsequent to the n-th phase period in the i-th waveform cycle are both higher than or lower than the source frequency in the n-th phase period.

### CROSS-REFERENCE TO RELATED APPLICATIONS

This application is a Continuation of PCT International Application No. PCT/JP2024/001919, filed on Jan. 23, 2024, which claims priority under 35 U.S.C. § 119(a) to Japanese Patent Application No. JP 2023-015585, filed in on Feb. 3, 2023, all of which are hereby expressly incorporated by reference into the present application.

### FIELD

Exemplary embodiments of the disclosure relate to a plasma processing device, a power supply system, and a control method.

### BACKGROUND

A plasma processing device performs plasma processing of substrates. The plasma processing device uses bias radio-frequency power to draw ions in plasma generated in a chamber toward a substrate. Patent Literature 1 below describes a plasma processing device that modulates the power level and the frequency of bias radio-frequency power.

### CITATION LIST

### Patent Literature

Patent Literature 1: Japanese Unexamined Patent Application Publication No. 2009-246091

### BRIEF SUMMARY

### Technical Problem

One or more aspects of the disclosure are directed to a technique for reducing variations in the source frequency of source radio-frequency power and reducing reflection of the source radio-frequency power.

### Solution to Problem

A plasma processing device according to one exemplary embodiment is provided. The plasma processing device includes a chamber, a substrate support, a bias power supply, a radio-frequency power supply, and a power supply controller. The substrate support is in the chamber. The bias power supply is electrically coupled to the substrate support to provide an electrical bias to the substrate support. The radio-frequency power supply provides source radio-frequency power to generate plasma in the chamber. The power supply controller provides, from the radio-frequency power supply, the source radio-frequency power having a predetermined source frequency f[i,n] in an n-th phase period of a plurality of phase periods in an i-th waveform cycle in a series of waveform cycles of the electrical bias. The power supply controller determines a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle. The power supply controller sets, in determination of the source frequency, the source frequency f[i+1,n] to a frequency obtained by adding a predetermined shift value Δf[n] to the source frequency f[i,n] when the degree of reflection of the source radio-frequency power in the n-th phase period in the i-th waveform cycle is a value satisfying a frequency change condition. The power supply controller sets, in determination of the source frequency, the source frequency f[i+1,n] to the source frequency f[i,n] when the degree of reflection does not satisfy the frequency change condition. The power supply controller maintains, in determination of the shift value Δf[n], a sign of the shift value Δf[n] to be unchanged when the degree of reflection of the source radio-frequency power in the n-th phase period is not on an upward trend in waveform cycles up to the i-th waveform cycle in the series. The power supply controller changes, in determination of the shift value Δf[n], the sign of the shift value Δf[n] when the degree of reflection in the n-th phase period is on an upward trend in the waveform cycles up to the i-th waveform cycle in the series. The power supply controller changes, in determination of the shift value Δf[n], the sign of the shift value Δf[n] when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

### Advantageous Effects

The technique according to one exemplary embodiment reduces variations in the source frequency of source radio-frequency power and reduces reflection of the source radio-frequency power.

### BRIEF DESCRIPTION OF DRAWINGS

FIG. 1 is a diagram of a plasma processing system, illustrating an example structure.

FIG. 2 is a diagram of a capacitively coupled plasma processing device, illustrating an example structure.

FIG. 3 is a graph showing an example waveform of electrical bias energy.

FIGS. 4A and 4B are each a timing chart of examples of source radio-frequency power and an electrical bias in the plasma processing device according to one exemplary embodiment.

FIG. 5 is a flowchart of a control method according to one exemplary embodiment.

FIG. 6 is a flowchart of example processing performed in step STb in FIG. 5.

FIG. 7 is a flowchart of example processing performed in step ST9 in FIG. 6.

FIG. 8 is a flowchart of another example of the processing performed in step STb in FIG. 5.

FIG. 9 is a flowchart of example processing performed in step ST9 in FIG. 8.

### DETAILED DESCRIPTION

Exemplary embodiments will now be described in detail with reference to the drawings. In the drawings, like reference numerals denote like or corresponding components.

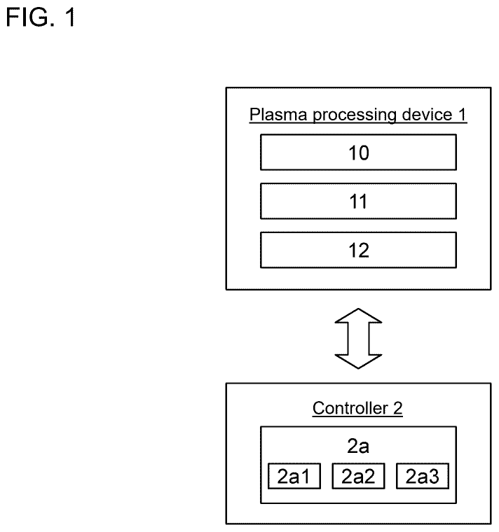

FIG. 1 is a diagram of a plasma processing system, illustrating an example structure. In one embodiment, the plasma processing system includes a plasma processing device 1 and a controller 2. The plasma processing system is an example of a substrate processing system. The plasma processing device 1 is an example of a substrate processing device. The plasma processing device 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP).

The controller 2 processes computer-executable instructions that cause the plasma processing device 1 to perform various steps described in one or more embodiments of the disclosure. The controller 2 may control the components of the plasma processing device 1 to perform the various steps described herein. In one embodiment, some or all of the components of the controller 2 may be included in the plasma processing device 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2a1 may be a programmable logic device such as a central processing unit (CPU) or a field-programmable gate array (FPGA). The storage 2a2 may include a random-access memory (RAM), a read-only memory (ROM), a hard disk drive (HDD), a solid-state drive (SSD), or a combination of these. The communication interface 2a3 may communicate with the plasma processing device 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

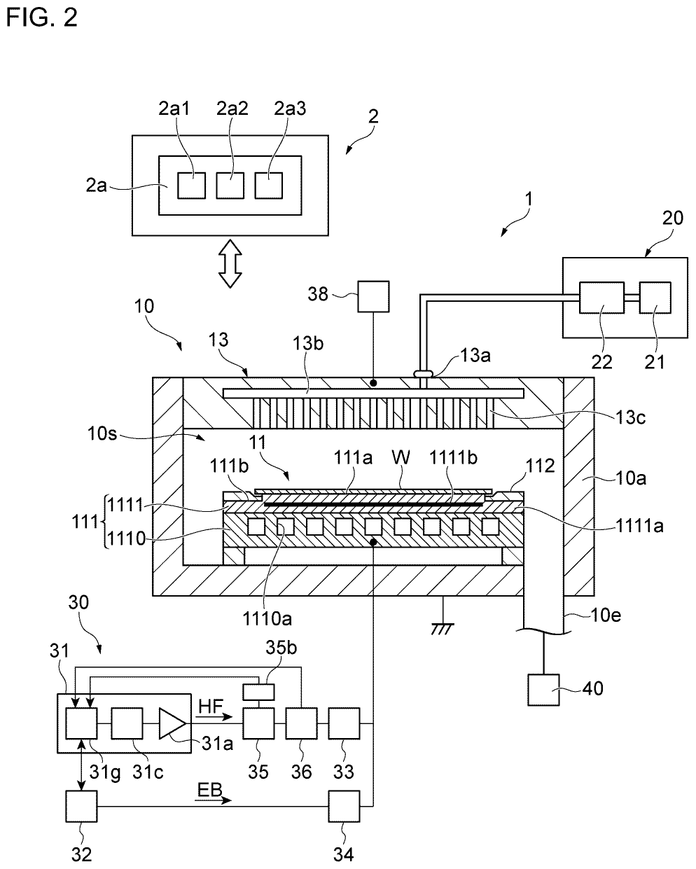

A capacitively coupled plasma processing device with an example structure will now be described as an example of the plasma processing device 1. FIG. 2 is a diagram of the capacitively coupled plasma processing device, illustrating an example structure.

The capacitively coupled plasma processing device 1 includes the plasma processing chamber 10, the gas supply 20, a power supply system 30, and the exhaust system 40. The plasma processing device 1 also includes the substrate support 11 and a gas guide unit. The gas guide unit allows at least one process gas to be introduced into the plasma processing chamber 10. The gas guide unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The substrate support 11 is electrically insulated from the housing of the plasma processing chamber 10.

The substrate support 11 includes a body 111 and a ring assembly 112. The body 111 includes a central area 111a for supporting a substrate W and an annular area 111b for supporting the ring assembly 112. The substrate W is, for example, a wafer. The annular area 111b of the body 111 surrounds the central area 111a of the body 111 in a plan view. The substrate W is placed on the central area 111a of the body 111. The ring assembly 112 is located on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one embodiment, the body 111 includes a base 1110 and an electrostatic chuck (ESC) 1111. The base 1110 includes a conductive member. The ESC 1111 is located on the base 1110. The ESC 1111 includes a ceramic member 1111a and an electrostatic electrode 1111b inside the ceramic member 1111a. The ceramic member 1111a includes the central area 111a. In one embodiment, the ceramic member 1111a also includes the annular area 111b. The annular area 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member.

The ring assembly 112 includes one or more annular members. In one embodiment, one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate to be a target temperature. The temperature control module may include a heater, a heat transfer medium, a channel 1110a, or a combination of these. The channel 1110a carries a heat transfer fluid such as brine or gas. In one embodiment, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central area 111a.

The shower head 13 introduces at least one process gas from the gas supply 20 into the plasma processing space 10s. The shower head 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one embodiment, the gas supply 20 supplies at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

The power supply system 30 includes a radio-frequency (RF) power supply 31 and a bias power supply 32. The RF power supply 31 serves as the plasma generator 12 in one embodiment. The RF power supply 31 generates source RF power HF. The source RF power HF has a source frequency. More specifically, the source RF power HF has a sinusoidal waveform with its frequency being the source frequency. The source frequency may be in a range of 10 to 150 MHz.

The RF power supply 31 is electrically coupled to an RF electrode through a matcher 33 to provide the source RF power HF to the RF electrode. The RF electrode may be located in the substrate support 11. The RF electrode may be the conductive member in the base 1110 or may be at least one electrode in the ceramic member 1111a. In some embodiments, the RF electrode may be an upper electrode. In response to the source RF power HF being provided to the RF electrode, plasma is generated from the gas in the chamber 10.

The matcher 33 has a variable impedance. The variable impedance of the matcher 33 is set to reduce reflection of the source RF power HF from a load. The matcher 33 may be controlled by, for example, the controller 2.

In one embodiment, the RF power supply 31 may include a signal generator 31g, a digital-to-analog (D/A) converter 31c, and an amplifier 31a. The signal generator 31g generates an RF signal having a source frequency fs. The signal generator 31g may include a programmable processor or a programmable logic device such as an FPGA.

The signal generator 31g has its output connected to the input of the D/A converter 31c. The D/A converter 31c converts an RF signal from the signal generator 31g to an analog signal. The D/A converter 31c has its output connected to the input of the amplifier 31a. The amplifier 31a amplifies the analog signal from the D/A converter 31c to generate the source RF power HF. The amplifier 31a has the amplification rate specified by the controller 2 for the RF power supply 31. The RF power supply 31 may or may not include the D/A converter 31c. When the RF power supply 31 does not include the D/A converter 31c, the signal generator 31g has its output connected to the input of the amplifier 31a, and the amplifier 31a amplifies the RF signal from the signal generator 31g to generate the source RF power HF.

The bias power supply 32 is electrically coupled to the substrate support 11. The bias power supply 32 is electrically coupled to a bias electrode in the substrate support 11 to provide an electrical bias EB to the bias electrode. The bias electrode may be the conductive member in the base 1110 or may be at least one electrode in the ceramic member 1111a. The bias electrode may also serve as the RF electrode. In response to the electrical bias EB being provided to the bias electrode, ions in the plasma are attracted toward the substrate W.

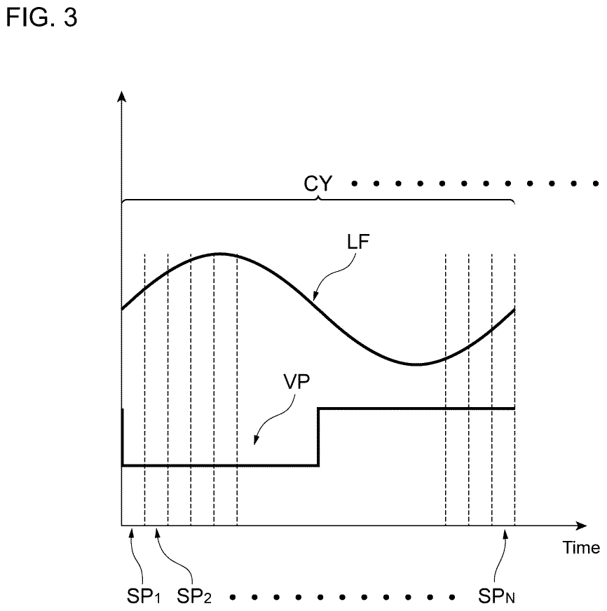

FIG. 3 will now be referred to in addition to FIG. 2. FIG. 3 is a graph showing an example waveform of an electrical bias. The bias power supply 32 cyclically provides the electrical bias EB having a waveform cycle CY to the bias electrode. More specifically, the electrical bias EB is repeatedly provided to the bias electrode in each of multiple waveform cycles CY The waveform cycle CY is defined by a bias frequency. The bias frequency is, for example, 50 kHz to 27 MHz inclusive. The waveform cycle CY has a duration that is the inverse of the bias frequency.

The electrical bias EB may be bias RF power LF having the bias frequency. In other words, the electrical bias EB may have a sinusoidal waveform with its frequency being the bias frequency. In this case, the bias power supply 32 is electrically coupled to the bias electrode through a matcher 34. The matcher 34 has a variable impedance that is set to reduce reflection of the bias RF power LF from the load.

In some embodiments, the electrical bias EB may include a voltage pulse VP. The voltage pulse VP is applied to the bias electrode in the waveform cycle CY. The voltage pulse VP is cyclically applied to the bias electrode at an interval equal to the duration of the waveform cycle CY The voltage pulse VP may have a waveform that is rectangular, triangular, or in any other shape. The voltage pulse VP has polarity that causes a potential difference between the plasma and the substrate W to draw ions in the plasma toward the substrate W. The voltage pulse VP is applied to the bias electrode to cause the waveform cycle CY to include a period during which the potential of the substrate W is negative. The voltage pulse VP applied to the bias electrode may have a negative potential, a positive potential, or a potential varying between positive and negative potentials. The voltage pulse VP may be a pulse of a negative voltage or a pulse of a negative direct current (DC) voltage. When the electrical bias EB is the voltage pulse VP, the plasma processing device 1 may or may not include the matcher 34.

As shown in FIG. 2, the plasma processing device 1 may further include a sensor 35 or a sensor 36, or both. The sensor 35 measures a power level Pr of the reflected wave of the source RF power HF from the load. The sensor 35 includes, for example, a directional coupler. The directional coupler may be located between the RF power supply 31 and the matcher 33. The sensor 35 may also measure a power level Pf of the traveling wave of the source RF power HF. The sensor 35 notifies the RF power supply 31 of the measured power level Pr of the reflected wave. In addition, the sensor 35 may or may not notify the RF power supply 31 of the power level Pf of the traveling wave. The sensor 35 may or may not notify the RF power supply 31 of a reflectance that is Pr/Pf. The reflectance may be determined by the RF power supply 31 based on the power level Pf and the power level Pr. A detection circuit 35b may be connected between the sensor 35 and the RF power supply 31. The power level Pf and the power level Pr may be determined based on the output from the detection circuit 35b.

The sensor 36 includes a voltage sensor and a current sensor. The sensor 36 measures a voltage Vs and a current Iₛ on a feed line coupling the RF power supply 31 and the RF electrode. The source RF power HF is provided to the RF electrode through the feed line. The sensor 36 may be located between the RF power supply 31 and the matcher 33. The RF power supply 31 is notified of the voltage Vs and the current Iₛ. The sensor 36 may or may not notify the RF power supply 31 of an impedance Z_{L} of the load of the RF power supply 31 determined based on the voltage Vs and the current Iₛ. The impedance Z_{L} may be determined by the RF power supply 31 based on the voltage Vs and the current Iₛ. The sensor 36 may or may not notify the RF power supply 31 of a phase difference θ between the voltage Vs and the current Iₛ. The phase difference θ may be determined by the RF power supply 31 based on the voltage Vs and the current Iₛ. The sensor 36 may or may not notify the RF power supply 31 of a reflection coefficient F determined based on the voltage Vs and the current Iₛ. The reflection coefficient F may be determined by the RF power supply 31 based on the voltage Vs and the current Iₛ.

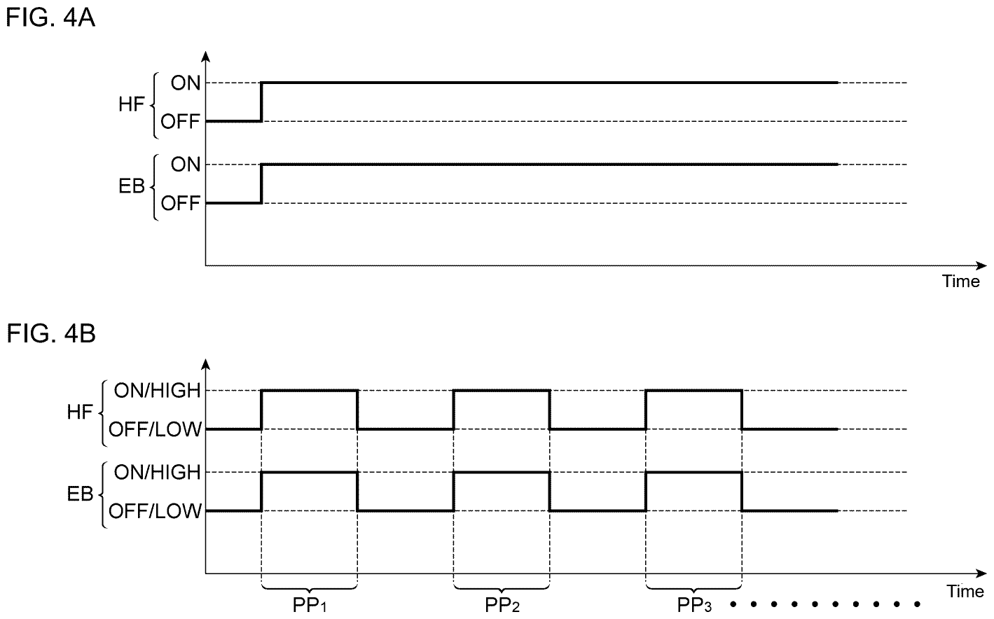

FIGS. 4A and 4B will now be referred to in addition to FIGS. 2 and 3. FIGS. 4A and 4B are each a timing chart of examples of source RF power and an electrical bias in the plasma processing device according to one exemplary embodiment. In these charts, the source RF power HF being ON indicates the source RF power HF being provided, and the source RF power HF being OFF indicates the source RF power HF being stopped. In FIG. 4B, the source RF power HF being HIGH indicates that the source RF power HF at a power level higher than the power level indicated by LOW is being provided. In FIG. 4B, the source RF power HF being LOW indicates that the source RF power HF at a power level lower than the power level indicated by HIGH is being provided. In the charts, the electrical bias EB being ON indicates the electrical bias EB being provided to the bias electrode, and the electrical bias EB being OFF indicates the electrical bias EB not being provided to the bias electrode. In FIG. 4B, the electrical bias EB being HIGH indicates that the electrical bias EB at a level higher than the level indicated by LOW is being provided. In FIG. 4B, the electrical bias EB being LOW indicates that the electrical bias EB at a level lower than the level indicated by HIGH is being provided. When the electrical bias EB is bias RF power LF, the level of the electrical bias EB is the power level of the bias RF power LF. When the electrical bias EB includes the voltage pulse VP, the level of the electrical bias EB is higher with higher energy of ions attracted to the substrate W. When the electrical bias EB includes the voltage pulse VP, the level of the electrical bias EB may be equal to the absolute value of the voltage level of the voltage pulse VP in the negative direction from the reference voltage (e.g., 0 V).

The RF power supply 31 provides the source RF power HF in parallel with the cyclic provision of the electrical bias EB from the bias power supply 32. More specifically, as shown in FIG. 4A, the electrical bias EB and the source RF power HF may be provided simultaneously and continuously from the start to the end of the process.

In some embodiments, as shown in FIG. 4B, the electrical bias EB and the source RF power HF may have their pulses provided in a synchronized manner. More specifically, the pulses of the electrical bias EB and the source RF power HF may be provided simultaneously in pulse periods PP₁, PP₂, and PP₃, . . . (or multiple pulse periods PP). Each of the multiple pulse periods PP includes multiple waveform cycles CY. In other words, the electrical bias EB is cyclically provided in each of the multiple pulse periods PP. The pulse of the electrical bias EB may be an on-off pulse that alternates between a period in which the electrical bias EB is provided (the ON state in FIG. 4B) and a period in which the electrical bias EB is stopped (the OFF state of ON in FIG. 4B). In some embodiments, the pulse of the electrical bias EB may be a high-low pulse that alternates between a high-level period (the HIGH state in FIG. 4B) and a low-level period (the LOW state in FIG. 4B). The pulse of the source RF power HF may be an on-off pulse that alternates between a period in which the source RF power HF is provided (the ON state in FIG. 4B) and a period in which the source RF power HF is stopped (the OFF state of ON in FIG. 4B). In some embodiments, the pulse of the source RF power HF may be a high-low pulse that alternates between a high-level period (the HIGH state in FIG. 4B) and a low-level period (the LOW state in FIG. 4B). The level of the source RF power HF may be modulated during periods in which the source RF power HF is in the ON state. The level of the source RF power HF may be modulated during periods in which the source RF power HF is at the HIGH level. The power level of the source RF power HF may be modulated during periods in which the source RF power HF is at the LOW level.

The RF power supply 31 adjusts the source frequency of the source RF power HF for each of multiple phase periods SP in each waveform cycle CY to reduce reflection of the source RF power HF from the load. The multiple phase periods SP are periods into which a waveform cycle CY is divided. As shown in FIG. 3, each waveform cycle CY is divided into multiple phase periods SP₁ to SP_{N} as the multiple phase periods SP. N is the number of phase periods in each waveform cycle CY

The RF power supply 31 may adjust the source frequency by adjusting the frequency of the RF signal with the signal generator 31g. The source frequency is determined by a power supply controller. The power supply controller may be located in the RF power supply 31, or may be located outside the RF power supply 31. The signal generator 31g may serve as the power supply controller, or another device in the RF power supply 31 may serve as the power supply controller. In some embodiments, the controller 2 may serve as the power supply controller.

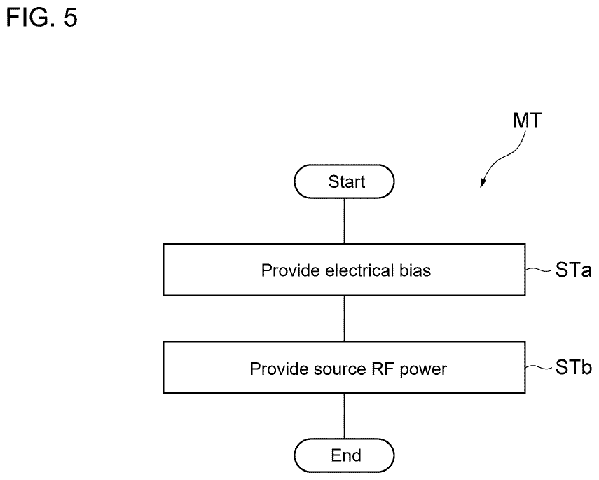

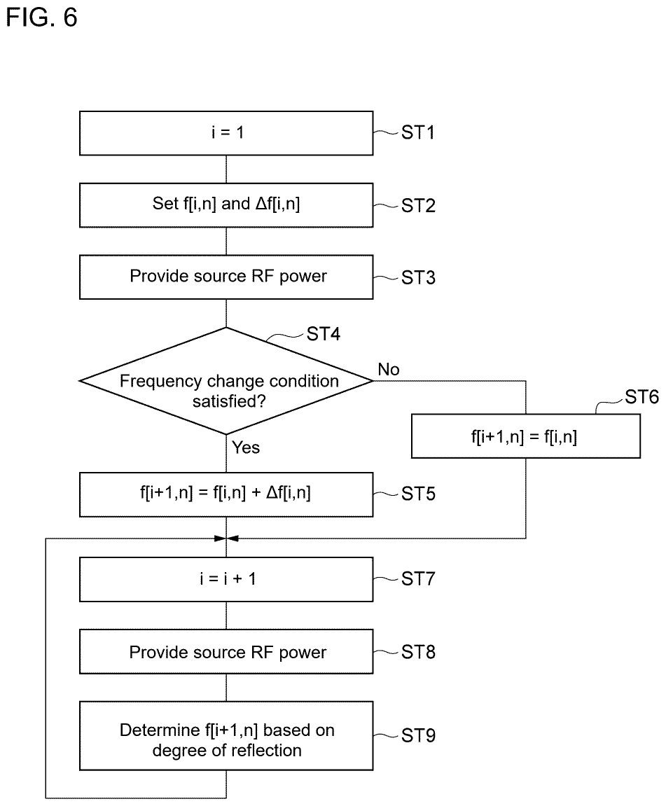

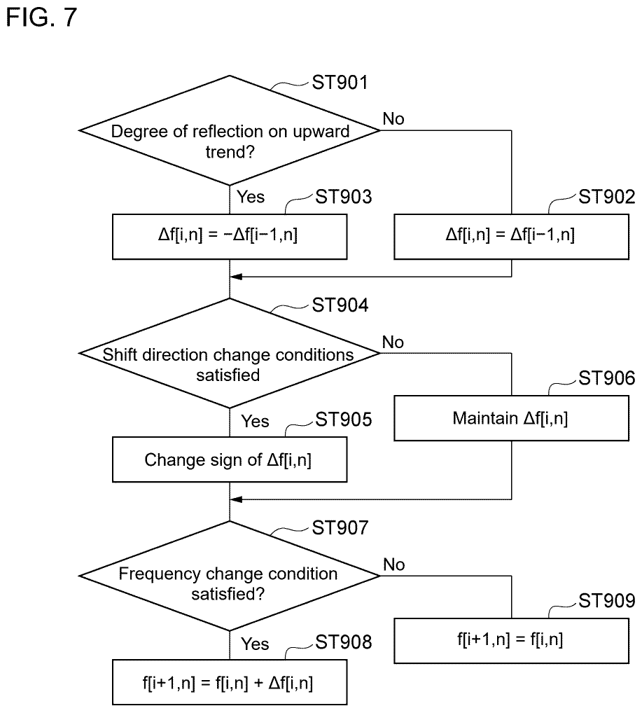

A method for controlling the source frequency will now be described with reference to FIGS. 5 to 7. The processing performed by the power supply controller to determine the source frequency will also be described. FIG. 5 is a flowchart of a control method according to one exemplary embodiment. FIG. 6 is a flowchart of example processing performed in step STb in FIG. 5. FIG. 7 is a flowchart of example processing performed in step ST9 in FIG. 6.

The control method shown in FIG. 5 (hereafter referred to as a method MT) includes steps STa and STb. In step STa, the electrical bias EB is provided from the bias power supply 32 to the bias electrode. In step STb, the source RF power HF is provided from the RF power supply 31 to the RF electrode to generate plasma from a gas in the chamber 10. As shown in FIG. 4A, the source RF power HF and the electrical bias EB may be provided simultaneously and continuously. In some embodiments, as shown in FIG. 4B, the pulsed source RF power HF and the pulsed electrical bias EB synchronized with each other may be provided.

In step STb, the power supply controller provides, from the RF power supply 31, a source RF power HF having a predetermined source frequency f[i,n] in an n-th phase period SP₁ in an i-th waveform cycle CYᵢ in a series CYS of waveform cycles CY The power supply controller then determines a source frequency f[i+Ifb,n] for the phase period SP₁ in the subsequent waveform cycle CY_{i+iFb} in the series CYS based on a degree of reflection Pd[i,n] of the source RF power HF in the phase period SP₁ in the waveform cycle CYᵢ. In other words, the power supply controller performs a feedback process for adjusting the source frequency f[i+Ifb,n] based on the degree of reflection P_{d}[i,n]. The value Ifb is an integer greater than or equal to 1.

The feedback process includes a first feedback process or a second feedback process, or both. The first feedback process is performed when the source RF power HF and the electrical bias EB are provided simultaneously and continuously as shown in FIG. 4A. In the first feedback process, the series CYS includes multiple waveform cycles CY that are repeated continuously.

The second feedback process is performed when the source RF power HF and the electrical bias EB are provided with their pulses being synchronized as shown in FIG. 4B. In the second feedback process, the series CYS includes waveform cycles CY at the same ordinal position in the respective pulse periods PP, or in other words, k-th waveform cycles CYₖ in the respective pulse periods PP. In the example shown in FIG. 4B, the second feedback process may be performed for all the waveform cycles CY in each pulse period PP. In some embodiments, the second feedback process may be performed for each of the first to the K₁-th waveform cycles CY in each pulse period PP, and the first feedback process may be performed for the (K₁+1)-th to the last waveform cycles CY in each pulse period PP. K₁ is an integer greater than or equal to 1. In some embodiments, the second feedback process may be performed for each of the first to the K₁-th waveform cycles CY in each pulse period PP, and for the (K₁+1)-th to the last waveform cycles CY in each pulse period PP, the source frequency in each phase period in the K₁-th waveform cycle CY may be used in the corresponding phase period.

An example of the feedback process in step STb will now be described. In the example feedback process described below, the value of Ifb described above is 1. However, as described above, the value of Ifb may be an integer greater than 1.

As shown in FIG. 6, step STb may include steps ST1 to ST9. Steps ST1 to ST9 are performed for each of the phase periods SP, or more specifically, for each of the phase periods SP₁ to SP_{N} in each waveform cycle CY in the series CYS.

In step ST1, the power supply controller sets the value i to 1. The value i indicates the ordinal position of the waveform cycle CY in the series CYS. In subsequent step ST2, the power supply controller sets the source frequency f[i,n] and the shift value Δf[i,n]. In step ST2, the source frequency f[i,n] and the shift value Δf[i,n], or more specifically, the source frequency f[1,n] and the shift value Δf[1,n] are set to their respective predetermined values.

In subsequent step ST3, the power supply controller provides the source RF power HF having the source frequency f[i,n] from the RF power supply 31 in the phase period SP₁ in the waveform cycle CYᵢ in the series CYS.

In subsequent step ST4, the power supply controller determines whether the degree of reflection P_{d}[i,n] of the source RF power HF in the phase period SP₁ in the waveform cycle CYᵢ in the series CYS is a value satisfying a frequency change condition. In step ST4, the frequency change condition is satisfied when the degree of reflection P_{d}[i,n] of the source RF power HF in the phase period SP₁ in the waveform cycle CYᵢ in the series CYS is greater than a threshold. In step ST4, the frequency change condition may be satisfied when P_{d}[i,n] is greater than a first threshold Pₜₕ₁[n]. The value of the first threshold Pₜₕ₁ may be the same or different for the multiple phase periods SP.

When the frequency change condition is satisfied in step ST4, in step ST5, the power supply controller sets the source frequency f[i+1,n] for the phase period SPₙ in the subsequent waveform cycle CYᵢ₊₁ in the series CYS using the formula below.

f[i+1,n]=f[i,n]+Δf[i,n]

When the frequency change condition is not satisfied in step ST4, in step ST5, the power supply controller sets the source frequency f[i+1,n] using the formula below.

f[i+1,n]=f[i,n]

In subsequent step ST7, the power supply controller increments i by 1. In subsequent step ST8, the power supply controller provides the source RF power HF having the source frequency f[i,n] from the RF power supply 31 in the phase period SPₙ in the waveform cycle CYᵢ in the series CYS.

In subsequent step ST9, the power supply controller determines the source frequency f[i+1,n] for the phase period SPₙ in the subsequent waveform cycle CYᵢ₊₁ in the series CYS based on the degree of reflection P_{d}[i,n].

As shown in FIG. 7, step ST9 starts with step ST901. In step ST901, the power supply controller determines whether the degree of reflection P_{d}[i,n] is on an upward trend. In step ST901, the power supply controller may determine that the degree of reflection P_{d}[i,n] is on an upward trend when P_{d}[i,n] is greater than P_{d}[i−1,n]. In some embodiments, the power supply controller may determine that the degree of reflection P_{d}[i,n] is on an upward trend when the degree of reflection in the n-th phase period SPₙ is on an upward trend over two or more waveform cycles CY up to the i-th waveform cycle CYᵢ in the series CYS.

When the degree of reflection P_{d}[i,n] is not on an upward trend in step ST901, the power supply controller maintains the sign of the shift value Δf[i,n] to be unchanged in step ST902. In other words, in step ST902, the power supply controller sets the shift value Δf[i,n] using the formula below.

Δf[i,n]=Δf[i−1,n]

When the degree of reflection P_{d}[i,n] is on an upward trend in step ST901, the power supply controller changes the sign of the shift value Δf[i,n] in step ST903. In other words, the power supply controller sets the shift value Δf[i,n] in step ST903 using the formula below.

Δf[i,n]=−Δf[i−1,n]

In step ST904, the power supply controller determines whether shift direction change conditions are satisfied. The shift direction change conditions are satisfied when a change in the source frequency is determined to be greater than a predetermined value based on comparison of the predetermined value with the absolute value of the difference between the source frequency f[i,n] and the source frequency f[i,n−u] in the (n−u)-th phase period SP₁₋ᵤ and comparison of the predetermined value with the absolute value of the difference between the source frequency f[i,n] and the source frequency f[i,n+u] in the (n+u)-th phase period SPₙ₊ᵤ and when both the source frequency f[i,n−u] and the source frequency f[i,n+u] are higher than or lower than the source frequency f[i,n] in the waveform cycle CYᵢ. For example, the shift direction change conditions are satisfied when the absolute value of the difference between the source frequencies f[i,n] and f[i,n−u] and the absolute value of the difference between the source frequencies f[i,n] and f[i,n+u] are each greater than a predetermined value and both the source frequencies f[i,n−u] and f[i,n+u] are higher than or lower than the source frequency f[i,n] in the waveform cycle CYᵢ.

In step ST904, u may be 1 or a value greater than 1. In step ST904, the shift direction change conditions may be satisfied when u is any value within a range from 1 to a value greater than 1.

When the shift direction change conditions are satisfied in step ST904, the power supply controller changes the sign of the shift value Δf[i,n] in step ST905. In other words, in step ST905, the power supply controller sets the shift value Δf[i,n] using the formula below.

Δf[i,n]=Δf[i−1,n]|*sign(f[i,n]−f[i,n−u]),
where sign( ) is a function that returns the sign of the numerical value in the parentheses, and u is a value with which the shift direction change conditions are satisfied.

When the shift direction change conditions are not satisfied in step ST904, the power supply controller maintains the sign of the shift value Δf[i,n] to be unchanged in step ST906. In other words, in step ST906, the power supply controller sets the shift value Δf[i,n] using the formula below.

Δf[i,n]=Δf[i,n]

In subsequent step ST907, the power supply controller determines whether the degree of reflection P_{d}[i,n] of the source RF power HF in the phase period SP₁ in the waveform cycle CYᵢ in the series CYS is a value satisfying the frequency change condition. In step ST907, the frequency change condition is satisfied when the degree of reflection P_{d}[i,n] of the source RF power HF in the phase period SP₁ in the waveform cycle CYᵢ in the series CYS is greater than a threshold.

In one embodiment, when the degree of reflection is determined to be less than the first threshold Pₜₕ₁[n] based on comparison between the degree of reflection in the phase period SPₙ in any of the waveform cycles in the series CYS and the first threshold Pₜₕ₁[n], the frequency change condition may or may not be satisfied in step ST907 until the degree of reflection is subsequently determined to be greater than the second threshold Pₜₕ₂[n] based on comparison between the degree of reflection in the phase period SP₁ and the second threshold Pₜₕ₂[n] in step ST907. The second threshold Pₜₕ₂[n] is greater than or equal to the first threshold Pₜₕ₁[n]. The second threshold Pₜₕ₂[n] may be greater than the first threshold Pₜₕ₁[n]. The value of the second threshold Pₜₕ₂[n] may be the same or different for the multiple phase periods SP.

More specifically, when the degree of reflection in the phase period SPₙ in any of the waveform cycles in the series CYS is less than or equal to the first threshold Pₜₕ₁[n], the second threshold Pₜₕ₂[n] may be used as a threshold that is to be compared with the degree of reflection in the phase period SP₁ subsequently in step ST907. When the degree of reflection in the phase period SP₁ in any of the waveform cycles in the series CYS is greater than the second threshold Pₜₕ₂[n], the first threshold Pₜₕ₁[n] may be used as a threshold that is to be compared with the degree of reflection in the phase period SPₙ subsequently in step ST907.

When the frequency change condition is satisfied in step ST907, in step ST908, the power supply controller sets the source frequency f[i+1,n] for the phase period SP₁ in the subsequent waveform cycle CYᵢ+1 in the series CYS using the formula below.

f[i+1,n]=f[i,n]+Δf[i,n]

When the frequency change condition is not satisfied in step ST907, the power supply controller sets the source frequency f[i+1,n] using the formula below in step ST909.

f[i+1,n]=f[i,n]

With the method MT, the source frequency f[i+1,n] is adjusted based on the degree of reflection P_{d}[i,n] to reduce reflection of the source RF power HF. In addition, the sign of the shift value is changed when the shift direction change conditions are satisfied, or in other words, when a large variation in the source frequency causing a large increase or decrease in the source frequency can follow a large decrease or increase in the source frequency within a waveform cycle CY. The method MT thus reduces large variations in the source frequency within a waveform cycle CY. As described above, the first threshold Pₜₕ₁ and the second threshold Pₜₕ₂ are used to determine whether the frequency change condition is satisfied. This reduces excess change in the source frequency. Repeating the method MT can achieve high reproducibility of temporal change in the source frequency.

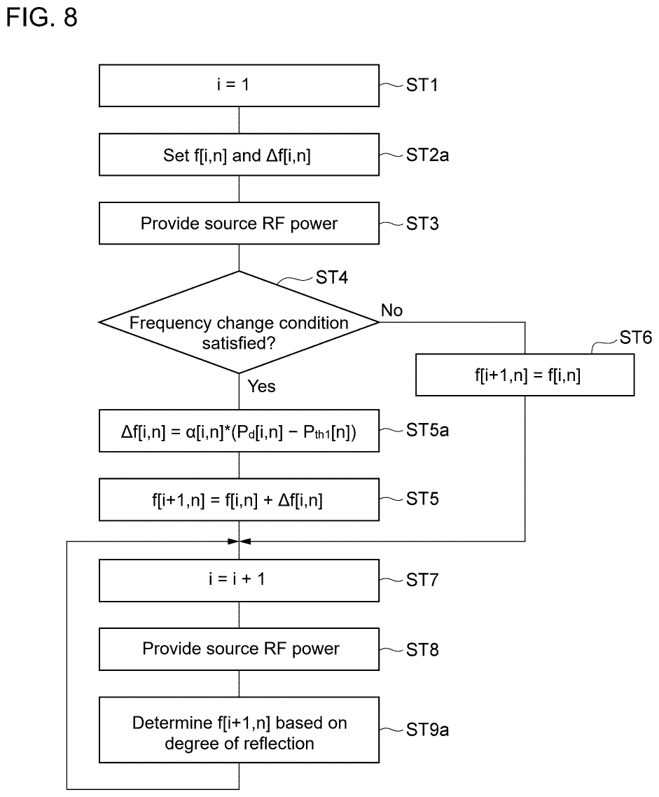

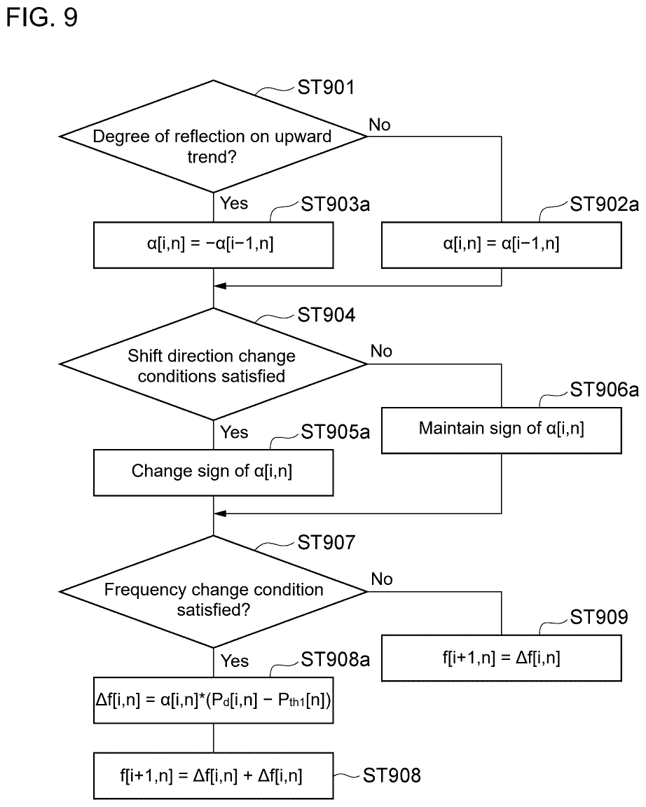

Another example of the processing performed in step STb will now be described with reference to FIGS. 8 and 9. FIG. 8 is a flowchart of another example of the processing performed in step STb in FIG. 5. FIG. 9 is a flowchart of example processing performed in step ST9 in FIG. 8. The processing performed in step STb in FIGS. 8 and 9 will now be described focusing on differences from the processing shown in FIGS. 5 and 6. In the processing shown in FIGS. 8 and 9, the power supply controller sets the shift value Δf[i,n] based on the degree of reflection P_{d}[i,n].

More specifically, as shown in FIG. 8, the power supply controller sets the source frequency f[i,n] and a coefficient α[i,n] in step ST2a between steps ST1 and ST3. In step ST2a, the source frequency f[i,n] and the coefficient α[i,n], or more specifically, the source frequency f[1,n] and the coefficient α[1,n] are set to respective predetermined values.

When the frequency change condition is satisfied in step ST4, the power supply controller sets the shift value Δf[i,n] in step ST5a between steps ST4 and ST5 using the formula below.

Δf[i,n]=α[i,n]*(P_{d}[i,n]−Pₜₕ₁[n])

In step ST9a subsequent to step ST8, the power supply controller determines the source frequency f[i+1,n] for the phase period SP₁ in the subsequent waveform cycle CYᵢ₊₁ in the series CYS based on the degree of reflection P_{d}[i,n].

As shown in FIG. 9, step ST9a starts with step ST901. When the degree of reflection P_{d}[i,n] is not on an upward trend in step ST901, the power supply controller maintains the sign of the coefficient α[i,n] to be unchanged in step ST902a. In other words, the power supply controller sets the coefficient α[i,n] in step ST902a using the formula below.

α[i,n]=α[i−1,n]

When the degree of reflection P_{d}[i,n] is on an upward trend in step ST901, the power supply controller changes the sign of the coefficient α[i,n] in step ST903a. In other words, the power supply controller sets the coefficient α[i,n] in step ST903a using the formula below.

α[i,n]=−α[i−1,n]

As shown in FIG. 9, when the shift direction change conditions are satisfied in step ST904, the power supply controller changes the sign of the coefficient α[i,n] in step ST905a. In other words, the power supply controller sets the coefficient α[i,n] in step ST905a using the formula below.

α[i,n]=|α[i−1,n]|*sign(f[i,n]−f[i,n−u]),
where u is a value with which the shift direction change conditions are satisfied.

When the shift direction change conditions are not satisfied in step ST904, the power supply controller maintains the sign of the coefficient α[i,n] to be unchanged in step ST906a. In other words, the power supply controller sets the coefficient α[i,n] in step ST906a using the formula below.

α[i,n]=α[i,n]

As shown in FIG. 9, when the frequency change condition is satisfied in step ST907, the power supply controller sets the shift value Δf[i,n] in step ST908a between steps ST907 and ST908 using the formula below.

Δf[i,n]=α[i,n]*(P_{d}[i,n]−Pₜₕ₁[n])

The degree of reflection P_{d}[i,n] will now be described. The degree of reflection P_{d}[i,n] is determined by obtaining evaluation values at multiple sample time points in the phase period SPₙ in the waveform cycle CYᵢ. The evaluation values reflect the magnitudes of reflection of the source RF power HF at the respective sample time points. Each of the multiple phase periods SP may include the same number of sample time points.

The degree of reflection P_{d}[i,n] is a representative value of the evaluation values obtained at the respective sample time points in the phase period SP₁ in the waveform cycle CYᵢ. The representative value is, for example, an average of the multiple evaluation values, a weighted average of the multiple evaluation values, or the maximum value of the multiple evaluation values. The evaluation values may each be the power level Pr of the reflected wave, the reflectance (Pr/Pf), the magnitude of the difference between the impedance Z_{L} and the characteristic impedance, or the reflection coefficient F.

In one embodiment, the degree of reflection P_{d}[i,n] is a weighted average of the evaluation values obtained at the multiple sample points in the phase period SP₁ in the waveform cycle CYᵢ. To calculate the weighted average, the power supply controller calculates the average of multiple values that are obtained by multiplying the multiple evaluation values by a window function. The window function has a weight that decreases based on the difference in time from the middle point of the phase period SPₙ. Examples of a window function include a triangular window, a Gauss window, a hanning window, and a hamming window. Using a weighted average obtained by applying such a window function can reduce variations in the calculated values of the degree of reflection P_{d}[i,n] that can result from the phase of the source RF power HF in each phase period SP.

Although various exemplary embodiments have been described above, the embodiments are not restrictive, and various additions, omissions, substitutions, and changes may be made. The components in the different embodiments may be combined to form another embodiment.

Various exemplary embodiments E1 to E17 included in the disclosure are described below.

### E1

A plasma processing device, comprising:
a chamber;
a substrate support in the chamber;
a bias power supply electrically coupled to the substrate support to provide an electrical bias to the substrate support;
a radio-frequency power supply configured to provide source radio-frequency power to generate plasma in the chamber; and
a power supply controller configured to
provide, from the radio-frequency power supply, the source radio-frequency power having a predetermined source frequency f[i,n] in an n-th phase period of a plurality of phase periods in an i-th waveform cycle in a series of waveform cycles of the electrical bias,
determine a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
set, in determination of the source frequency, the source frequency f[i+1,n] to a frequency obtained by adding a predetermined shift value Δf[n] to the source frequency f[i,n] when the degree of reflection of the source radio-frequency power in the n-th phase period in the i-th waveform cycle is a value satisfying a frequency change condition and set, in determination of the source frequency, the source frequency f[i+1,n] to the source frequency f[i,n] when the degree of reflection does not satisfy the frequency change condition,
maintain, in determination of the shift value Δf[n], a sign of the shift value Δf[n] to be unchanged when the degree of reflection of the source radio-frequency power in the n-th phase period is not on an upward trend in waveform cycles up to the i-th waveform cycle in the series and change, in determination of the shift value Δf[n], the sign of the shift value Δf[n] when the degree of reflection in the n-th phase period is on an upward trend in the waveform cycles up to the i-th waveform cycle in the series, and
change, in determination of the shift value Δf[n], the sign of the shift value Δf[n] when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

### E2

The plasma processing device according to E1, wherein
the power supply controller maintains the source frequency for the n-th phase period to be unchanged when the degree of reflection is determined to be less than a first threshold based on comparison between the degree of reflection in the n-th phase period in the i-th waveform cycle in the series and the first threshold and until the degree of reflection is determined to be greater than a second threshold based on comparison between the degree of reflection in the n-th phase period in a waveform cycle subsequent to the i-th waveform cycle in the series and the second threshold, and
the second threshold is greater than or equal to the first threshold.

### E3

The plasma processing device according to E1 or E2, wherein
the power supply controller changes the sign of the shift value Δf[n] when the degree of reflection in the n-th phase period is on an upward trend over two or more waveform cycles up to the i-th waveform cycle in the series.

### E4

The plasma processing device according to any one of E1 to E3, wherein
the power supply controller changes the sign of the shift value Δf[n] when a change in the source frequency is determined to be greater than the predetermined value based on the comparison of the predetermined value with the absolute value of a difference between the source frequency f[i,n] and the source frequency f[i,n−u] and the comparison of the predetermined value with the absolute value of a difference between the source frequency f[i,n] and the source frequency f[i,n+u] in the i-th waveform cycle in the series and when both the source frequency f[i,n−u] and the source frequency f[i,n+u] are higher than or lower than the source frequency f[i,n] with u being a value within a range from 1 to a value greater than 1.

### E5

The plasma processing device according to any one of E1 to E4, wherein
the power supply controller uses, as the degree of reflection in the n-th phase period, an average value obtained by multiplying, by a window function, a plurality of evaluation values each reflecting a magnitude of reflection of the source radio-frequency power at a corresponding sample time point of a plurality of sample time points in the n-th phase period, and
the window function has a weight decreasing based on difference in time from a middle point of the n-th phase period.

### E6

The plasma processing device according to E5, wherein
each of the plurality of phase periods includes a same number of the plurality of sample time points.

### E7

The plasma processing device according to E5 or E6, wherein
each of the plurality of evaluation values is calculated based on a power level of a reflected wave of the source radio-frequency power or a reflectance of the source radio-frequency power.

### E8

The plasma processing device according to any one of E1 to E7, wherein
the electrical bias is bias radio-frequency power having a bias frequency being an inverse of a duration of each of the waveform cycles or includes a voltage pulse cyclically applied at an interval equal to the duration of each of the waveform cycles.

### E9

A power supply system, comprising:
a bias power supply configured to provide an electrical bias to a substrate support in a chamber in a plasma processing device;
a radio-frequency power supply configured to provide source radio-frequency power to generate plasma in the chamber; and
a power supply controller configured to
   provide, from the radio-frequency power supply, the source radio-frequency power having a predetermined source frequency f[i,n] in an n-th phase period of a plurality of phase periods in an i-th waveform cycle in a series of waveform cycles of the electrical bias,
   determine a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
   set, in determination of the source frequency, the source frequency f[i+1,n] to a frequency obtained by adding a predetermined shift value Δf[n] to the source frequency f[i,n] when the degree of reflection of the source radio-frequency power in the n-th phase period in the i-th waveform cycle is a value satisfying a frequency change condition and set, in determination of the source frequency, the source frequency f[i+1,n] to the source frequency f[i,n] when the degree of reflection does not satisfy the frequency change condition,
   maintain, in determination of the shift value Δf[n], a sign of the shift value Δf[n] to be unchanged when the degree of reflection of the source radio-frequency power in the n-th phase period is not on an upward trend in waveform cycles up to the i-th waveform cycle in the series and change, in determination of the shift value Δf[n], the sign of the shift value Δf[n] when the degree of reflection in the n-th phase period is on an upward trend in the waveform cycles up to the i-th waveform cycle in the series, and
   change, in determination of the shift value Δf[n], the sign of the shift value Δf[n] when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

### E10

A control method, comprising:
(a) providing an electrical bias from a bias power supply to a substrate support in a chamber in a plasma processing device; and
(b) providing source radio-frequency power from a radio-frequency power supply to generate plasma in the chamber, (b) including
(b-1) providing, from the radio-frequency power supply, the source radio-frequency power having a predetermined source frequency f[i,n] in an n-th phase period of a plurality of phase periods in an i-th waveform cycle in a series of waveform cycles of the electrical bias, and
(b-2) determining a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
wherein in (b-2), the source frequency f[i+1,n] is set to a frequency obtained by adding a predetermined shift value Δf[n] to the source frequency f[i,n] when the degree of reflection of the source radio-frequency power in the n-th phase period in the i-th waveform cycle is a value satisfying a frequency change condition, and the source frequency f[i+1,n] is set to the source frequency f[i,n] when the degree of reflection does not satisfy the frequency change condition, and
in determination of the shift value Δf[n],
   a sign of the shift value Δf[n] is maintained to be unchanged when the degree of reflection of the source radio-frequency power in the n-th phase period is not on an upward trend in waveform cycles up to the i-th waveform cycle in the series, and the sign of the shift value Δf[n] is changed when the degree of reflection in the n-th phase period is on an upward trend in the waveform cycles up to the i-th waveform cycle in the series, and
   the sign of the shift value Δf[n] is changed when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

### E11

The control method according to E10, wherein
in (b), the source frequency for the n-th phase period is maintained to be unchanged when the degree of reflection is determined to be less than a first threshold based on comparison between the degree of reflection in the n-th phase period in the i-th waveform cycle in the series and the first threshold and until the degree of reflection is determined to be greater than a second threshold based on comparison between the degree of reflection in the n-th phase period in a waveform cycle subsequent to the i-th waveform cycle in the series and the second threshold, and
the second threshold is greater than or equal to the first threshold.

### E12

The control method according to E10 or E11, wherein
in the determination of the shift value Δf[n], the sign of the shift value Δf[n] is changed when the degree of reflection in the n-th phase period is on an upward trend over two or more waveform cycles up to the i-th waveform cycle in the series.

### E13

The control method according to any one of E10 to E12, wherein
in the determination of the shift value Δf[n], the sign of the shift value Δf[n] is changed when a change in the source frequency is determined to be greater than the predetermined value based on the comparison of the predetermined value with the absolute value of a difference between the source frequency f[i,n] and the source frequency f[i,n−u] and the comparison of the predetermined value with the absolute value of a difference between the source frequency f[i,n] and the source frequency f[i,n+u] in the i-th waveform cycle in the series and when both the source frequency f[i,n−u] and the source frequency f[i,n+u] are higher than or lower than the source frequency f[i,n] with u being a value within a range from 1 to a value greater than 1.

### E14

The control method according to any one of E10 to E13, wherein
the degree of reflection in the n-th phase period is an average value obtained by multiplying, by a window function, a plurality of evaluation values each reflecting a magnitude of reflection of the source radio-frequency power at a corresponding sample time point of a plurality of sample time points in the n-th phase period, and
the window function has a weight decreasing based on difference in time from a middle point of the n-th phase period.

### E15

The control method according to E14, wherein
each of the plurality of phase periods includes a same number of the plurality of sample time points.

### E16

The control method according to E14 or E15, wherein
each of the plurality of evaluation values is calculated based on a power level of a reflected wave of the source radio-frequency power or a reflectance of the source radio-frequency power.

### E17

The control method according to any one of E10 to E16, wherein
the electrical bias is bias radio-frequency power having a bias frequency being an inverse of a duration of each of the waveform cycles or includes a voltage pulse cyclically applied at an interval equal to the duration of each of the waveform cycles.

Various exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

### REFERENCE SIGNS LIST

1 Plasma processing device
10 Chamber
11 Substrate support
31 RF power supply
32 Bias power supply

1. A plasma processing device, comprising:
a chamber;
a substrate support in the chamber;
a bias power supply electrically coupled to the substrate support to provide an electrical bias to the substrate support;
a radio-frequency power supply configured to provide source radio-frequency power to generate plasma in the chamber; and
power supply circuitry configured to:
provide, from the radio-frequency power supply, the source radio-frequency power having a source frequency f[i,n] in an n-th phase period of a plurality of phase periods in an i-th waveform cycle in a series of waveform cycles of the electrical bias,
determine a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
set, in determination of the source frequency, the source frequency f[i+1,n] to a frequency obtained by adding a shift value Δf[n] to the source frequency f[i,n] when the degree of reflection of the source radio-frequency power in the n-th phase period in the i-th waveform cycle is a value satisfying a frequency change condition and set, in determination of the source frequency, the source frequency f[i+1,n] to the source frequency f[i,n] when the degree of reflection does not satisfy the frequency change condition,
maintain, in determination of the shift value Δf[n], a sign of the shift value Δf[n] to be unchanged when the degree of reflection of the source radio-frequency power in the n-th phase period is not on an upward trend in waveform cycles up to the i-th waveform cycle in the series and change, in determination of the shift value Δf[n], the sign of the shift value Δf[n] when the degree of reflection in the n-th phase period is on an upward trend in the waveform cycles up to the i-th waveform cycle in the series, and
change, in determination of the shift value Δf[n], the sign of the shift value Δf[n] when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

2. The plasma processing device according to claim 1, wherein
the power supply circuitry maintains the source frequency for the n-th phase period to be unchanged when the degree of reflection is determined to be less than a first threshold based on comparison between the degree of reflection in the n-th phase period in the i-th waveform cycle in the series and the first threshold and until the degree of reflection is determined to be greater than a second threshold based on comparison between the degree of reflection in the n-th phase period in a waveform cycle subsequent to the i-th waveform cycle in the series and the second threshold, and
the second threshold is greater than or equal to the first threshold.

3. The plasma processing device according to claim 1, wherein
the power supply circuitry changes the sign of the shift value Δf[n] when the degree of reflection in the n-th phase period is on an upward trend over two or more waveform cycles up to the i-th waveform cycle in the series.

4. The plasma processing device according to claim 1, wherein
the power supply circuitry changes the sign of the shift value Δf[n] when a change in the source frequency is determined to be greater than the predetermined value based on the comparison of the predetermined value with the absolute value of a difference between the source frequency f[i,n] and the source frequency f[i,n−u] and the comparison of the predetermined value with the absolute value of a difference between the source frequency f[i,n] and the source frequency f[i,n+u] in the i-th waveform cycle in the series and when both the source frequency f[i,n−u] and the source frequency f[i,n+u] are higher than or lower than the source frequency f[i,n] with u being a value within a range from 1 to a value greater than 1.

5. The plasma processing device according to claim 1, wherein
the power supply circuitry uses, as the degree of reflection in the n-th phase period, an average value obtained by multiplying, by a window function, a plurality of evaluation values each reflecting a magnitude of reflection of the source radio-frequency power at a corresponding sample time point of a plurality of sample time points in the n-th phase period, and
the window function has a weight decreasing based on difference in time from a middle point of the n-th phase period.

6. The plasma processing device according to claim 5, wherein
each of the plurality of phase periods includes a same number of the plurality of sample time points.

7. The plasma processing device according to claim 5, wherein
each of the plurality of evaluation values is calculated based on a power level of a reflected wave of the source radio-frequency power or a reflectance of the source radio-frequency power.

8. The plasma processing device according to claim 1, wherein
the electrical bias is bias radio-frequency power having a bias frequency being an inverse of a duration of each of the waveform cycles or includes a voltage pulse cyclically applied at an interval equal to the duration of each of the waveform cycles.

9. A power supply system, comprising:
a bias power supply configured to provide an electrical bias to a substrate support in a chamber in a plasma processing device;
a radio-frequency power supply configured to provide source radio-frequency power to generate plasma in the chamber; and
power supply circuitry configured to:
provide, from the radio-frequency power supply, the source radio-frequency power having a source frequency f[i,n] in an n-th phase period of a plurality of phase periods in an i-th waveform cycle in a series of waveform cycles of the electrical bias,
determine a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
set, in determination of the source frequency, the source frequency f[i+1,n] to a frequency obtained by adding a shift value Δf[n] to the source frequency f[i,n] when the degree of reflection of the source radio-frequency power in the n-th phase period in the i-th waveform cycle is a value satisfying a frequency change condition and set, in determination of the source frequency, the source frequency f[i+1,n] to the source frequency f[i,n] when the degree of reflection does not satisfy the frequency change condition,
maintain, in determination of the shift value Δf[n], a sign of the shift value Δf[n] to be unchanged when the degree of reflection of the source radio-frequency power in the n-th phase period is not on an upward trend in waveform cycles up to the i-th waveform cycle in the series and change, in determination of the shift value Δf[n], the sign of the shift value Δf[n] when the degree of reflection in the n-th phase period is on an upward trend in the waveform cycles up to the i-th waveform cycle in the series, and
change, in determination of the shift value Δf[n], the sign of the shift value Δf[n] when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

10. The power supply system according to claim 9, wherein
the power supply circuitry maintains the source frequency for the n-th phase period to be unchanged when the degree of reflection is determined to be less than a first threshold based on comparison between the degree of reflection in the n-th phase period in the i-th waveform cycle in the series and the first threshold and until the degree of reflection is determined to be greater than a second threshold based on comparison between the degree of reflection in the n-th phase period in a waveform cycle subsequent to the i-th waveform cycle in the series and the second threshold, and
the second threshold is greater than or equal to the first threshold.

11. The power supply system according to claim 9, wherein
the power supply circuitry changes the sign of the shift value Δf[n] when the degree of reflection in the n-th phase period is on an upward trend over two or more waveform cycles up to the i-th waveform cycle in the series.

12. The power supply system according to claim 9, wherein
the power supply circuitry changes the sign of the shift value Δf[n] when a change in the source frequency is determined to be greater than the predetermined value based on the comparison of the predetermined value with the absolute value of a difference between the source frequency f[i,n] and the source frequency f[i,n−u] and the comparison of the predetermined value with the absolute value of a difference between the source frequency f[i,n] and the source frequency f[i,n+u] in the i-th waveform cycle in the series and when both the source frequency f[i,n−u] and the source frequency f[i,n+u] are higher than or lower than the source frequency f[i,n] with u being a value within a range from 1 to a value greater than 1.

13. A control method, comprising:
(a) providing an electrical bias from a bias power supply to a substrate support in a chamber in a plasma processing device; and
(b) providing source radio-frequency power from a radio-frequency power supply to generate plasma in the chamber, (b) including
(b-1) providing, from the radio-frequency power supply, the source radio-frequency power having a predetermined source frequency f[i,n] in an n-th phase period of a plurality of phase periods in an i-th waveform cycle in a series of waveform cycles of the electrical bias, and
(b-2) determining a source frequency f[i+1,n] of the source radio-frequency power for the n-th phase period in a waveform cycle subsequent to the i-th waveform cycle in the series based on a degree of reflection of the source radio-frequency power in the n-th phase period in the i-th waveform cycle,
wherein in (b-2), the source frequency f[i+1,n] is set to a frequency obtained by adding a predetermined shift value Δf[n] to the source frequency f[i,n] when the degree of reflection of the source radio-frequency power in the n-th phase period in the i-th waveform cycle is a value satisfying a frequency change condition, and the source frequency f[i+1,n] is set to the source frequency f[i,n] when the degree of reflection does not satisfy the frequency change condition, and
in determination of the shift value Δf[n],
a sign of the shift value Δf[n] is maintained to be unchanged when the degree of reflection of the source radio-frequency power in the n-th phase period is not on an upward trend in waveform cycles up to the i-th waveform cycle in the series, and the sign of the shift value Δf[n] is changed when the degree of reflection in the n-th phase period is on an upward trend in the waveform cycles up to the i-th waveform cycle in the series, and
the sign of the shift value Δf[n] is changed when a change in the source frequency is determined to be greater than a predetermined value based on comparison of the predetermined value with an absolute value of a difference between the source frequency f[i,n] and a source frequency f[i,n−u] of the source radio-frequency power in an (n−u)-th phase period and comparison of the predetermined value with an absolute value of a difference between the source frequency f[i,n] and a source frequency f[i,n+u] of the source radio-frequency power in an (n+u)-th phase period in the i-th waveform cycle and when both the source frequency f[i,n−u] and the source frequency f[i,n+u] are higher than or lower than the source frequency f[i,n].

14. The control method according to claim 13, wherein
in (b), the source frequency for the n-th phase period is maintained to be unchanged when the degree of reflection is determined to be less than a first threshold based on comparison between the degree of reflection in the n-th phase period in the i-th waveform cycle in the series and the first threshold and until the degree of reflection is determined to be greater than a second threshold based on comparison between the degree of reflection in the n-th phase period in a waveform cycle subsequent to the i-th waveform cycle in the series and the second threshold, and
the second threshold is greater than or equal to the first threshold.

15. The control method according to claim 13, wherein
in the determination of the shift value Δf[n], the sign of the shift value Δf[n] is changed when the degree of reflection in the n-th phase period is on an upward trend over two or more waveform cycles up to the i-th waveform cycle in the series.

16. The control method according to claim 13, wherein
in the determination of the shift value Δf[n], the sign of the shift value Δf[n] is changed when a change in the source frequency is determined to be greater than the predetermined value based on the comparison of the predetermined value with the absolute value of a difference between the source frequency f[i,n] and the source frequency f[i,n−u] and the comparison of the predetermined value with the absolute value of a difference between the source frequency f[i,n] and the source frequency f[i,n+u] in the i-th waveform cycle in the series and when both the source frequency f[i,n−u] and the source frequency f[i,n+u] are higher than or lower than the source frequency f[i,n] with u being a value within a range from 1 to a value greater than 1.

17. The control method according to claim 13, wherein
the degree of reflection in the n-th phase period is an average value obtained by multiplying, by a window function, a plurality of evaluation values each reflecting a magnitude of reflection of the source radio-frequency power at a corresponding sample time point of a plurality of sample time points in the n-th phase period, and
the window function has a weight decreasing based on difference in time from a middle point of the n-th phase period.

18. The control method according to claim 17, wherein
each of the plurality of phase periods includes a same number of the plurality of sample time points.

19. The control method according to claim 17, wherein
each of the plurality of evaluation values is calculated based on a power level of a reflected wave of the source radio-frequency power or a reflectance of the source radio-frequency power.

20. The control method according to claim 13, wherein
the electrical bias is bias radio-frequency power having a bias frequency being an inverse of a duration of each of the waveform cycles or includes a voltage pulse cyclically applied at an interval equal to the duration of each of the waveform cycles.
